(19) United States
(12) Patent Application Publication
(10) Pub. No.: US 2013/0032381 A1
(43) Pub. Date: Feb. 7, 2013

(54) FLEXIBLE WIRING MODULE AND FLEXIBLE WIRING DEVICE

(71) Applicants: Kohei Hiyama, Yokohama-shi (JP); Hiroshi Uemura, Yokohama-shi (JP); Hideto Furuyama, Yokohama-shi (JP)

(72) Inventors: Kohei Hiyama, Yokohama-shi (JP); Hiroshi Uemura, Yokohama-shi (JP); Hideto Furuyama, Yokohama-shi (JP)

(73) Assignee: KABUSHIKI KAISHA TOSHIBA, Tokyo (JP)

(21) Appl. No.: 13/305,843

(22) Filed: Nov. 29, 2011

(30) Foreign Application Priority Data
Aug. 2, 2011 (JP) 2011-169101

(51) Int. Cl. H05K 1/02

(52) U.S. Cl. 174/254

(57) ABSTRACT

According to one embodiment, a flexible wiring module includes a flexible wiring board which comprises electric wiring lines and an insulating layer that covers the surfaces of the electric wiring lines and which has a pair of end areas separate from each other in a wiring length direction and a wiring area sandwiched between the end areas. At least one through slit is made in the wiring area so as to connect the end areas, thereby dividing the wiring area into wiring fins. A stacked part where at least a part of the wiring fins are stacked in a thickness direction of the wiring fins is bundled together with a conductive band to form a wire-bundle area. In the wire-bundle area, the electric wiring line of at least one of the wiring fins is exposed and direct contact with the band.

### CROSS-REFERENCE TO RELATED APPLICATIONS

This application is based upon and claims the benefit of priority from prior Japanese Patent Application No. 2011-169101, filed Aug. 2, 2011, the entire contents of which are incorporated herein by reference.

### FIELD

Embodiments described herein relate generally to a flexible wiring module and a flexible wiring device.

### BACKGROUND

A flexible wiring board has been used to install wiring in a mechanical moving part and a curved surface part of an electronic device. In addition, a flexible wiring module has been proposed. The flexible wiring module is such that a plurality of fins are formed by making cuts in a flexible wiring board in a direction in which the board extends and the fins are bundled together.

### BRIEF DESCRIPTION OF THE DRAWINGS

FIG. 1 is a top view showing a schematic configuration of a flexible wiring module according to a first embodiment;

FIGS. 2A and 2B are schematic sectional views taken along line A-A′ and line B-B′ of FIG. 1, respectively;

FIG. 3 is a top view showing a schematic configuration of a flexible wiring device according to the first embodiment;

FIGS. 4A to 4E are top views to explain processes of manufacturing a flexible wiring module according to the first embodiment;

FIG. 5 is a schematic sectional view showing the configuration of a main part of a flexible wiring module according to a second embodiment;

FIG. 6 is a schematic sectional view showing the configuration of a main part of a flexible wiring module according to a third embodiment; and

FIG. 7 is a schematic sectional view showing the configuration of a main part of a flexible wiring module according to a fourth embodiment.

### DETAILED DESCRIPTION

In general, according to one embodiment, a flexible wiring module comprises a flexible wiring board which comprises a plurality of electric wiring lines and an insulating layer that covers the surfaces of the electric wiring lines and which has a pair of end areas separate from each other in a wiring length direction and a wiring area sandwiched between the end areas. At least one through slit is made in the wiring area so as to connect the end areas, thereby dividing the wiring area into a plurality of wiring fins. A stacked part where at least a part of the wiring fins are stacked in a thickness direction of the wiring fins is bundled together with a conductive band to form a wire-bundle area. In the wire-bundle area, the electric wiring line of at least one of the wiring fins is exposed and direct contact with the band. Hereinafter, referring to the accompanying drawings, embodiments will be explained. Although an explanation will be given using specific materials and configurations as examples, other materials and configurations may be used, provided that they have the same functions as those in the examples. Therefore, materials and configurations are not restricted to the embodiments described below.

In the embodiment below, to simplify the explanation, only the shape of the substrate of a flexible wring module is sometimes shown, with the wiring pattern including electric wiring omitted. It goes without saying that the wiring pattern is arbitrary.

### First Embodiment

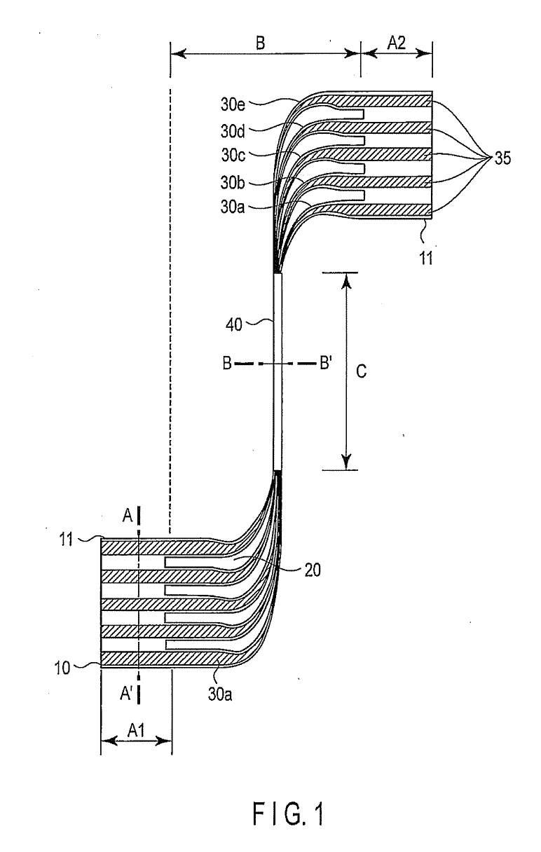

FIG. 1 is a top view showing a schematic configuration of a flexible wiring module according to a first embodiment.

In the flexible wiring module of the first embodiment, a plurality of through slits (penetration slits) 20 are made in a wiring area B excluding end areas 11 (A1, A2) in a flexible wiring board 10. That is, the through slits 20 are formed in the wiring area B so as to connect the end areas 11 and penetrated the flexible wiring board 10. The through slits 20 divide the wiring area B of the wiring board 10 into a plurality of wiring fins 30 (30a to 30e). The number of slits 20 and the number of wiring fins 30 are illustrative and not restrictive. The divided wiring fins 30 are bundled together with a wire-bundle band 40 in a bundling area C in the middle of the wiring area B.

Electric wiring lines 35 extend from one end area A1, pass through the respective wiring fins 30a to 30e, and reach the other end area A2. The bundling area C is an area where the wiring fins 30 are bundled together and makes a flexible wire bundle that can be bent in a normal direction to the plane of the end area 11 (or at right angle with the drawing sheet) and in a horizontal direction (or in parallel with the drawing sheet).

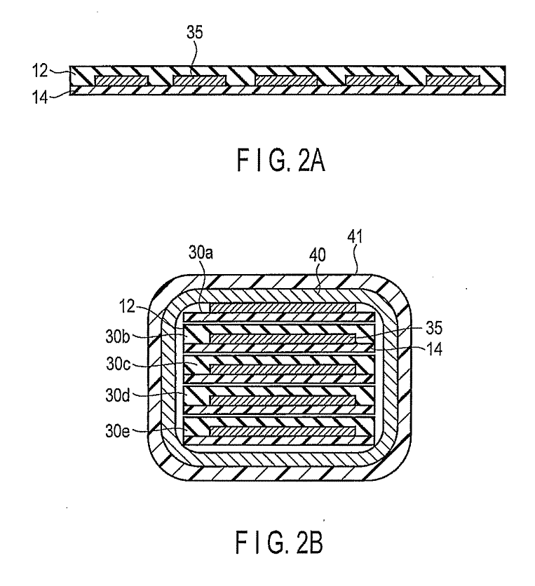

An example of the configuration of the flexible wiring board 10 used in the first embodiment is a three-layer laminate unit composed of, for example, a base film 14 made of polyimide 25-gm thick, an electric wiring line 35 made of a 25-gm-thick rolled copper foil, and a cover lay 12 made of polyimide 25-gm thick as shown by a sectional view of FIG. 2A taken along line A-A′ of FIG. 1. The overall flexible wiring board is 10 mm wide and 150 mm long. Both ends of the flexible wiring board 10 are left 10 mm from the edge as the end areas A1 and A2. Slits 20 0.1 mm wide are made at a 1-mm pitch in the wiring board, thereby forming ten 0.9-mm-wide, 130-mm-long fins. The wiring fins 30 are bundled together.

Therefore, it is desirable that all the wiring fins 30 should have almost the same width. Of course, an electric wiring pattern made of Cu or the like is prevented from being formed in the parts where through slits 20 are made. It is desirable that the wiring fins 30 should have a width not greater than 1/10 of the length of the wiring area from the viewpoint of flexibility. The same holds true for the embodiments below.

Next, the wiring fin groups are stacked one on top of another in the order in which they line up and are tied together. Then, for example, metal sheets obtained by cutting, for example, a Cu foil or Al foil into 5-mm-wide strips are wound around a part of the wiring area B as shown in FIG. 1, thereby bundling the wiring fin groups together. It is desirable that the length of the bundling area C should be, for example, 100 mm and provided almost in the center of the wiring area B. At this time, the wiring fins 30 are kept unfixed so as to allow the fins 30 to move inside the wire-bundle band 40, which makes it easy for the wiring fins 30 to expand and contract and for bending stress to be alleviated when the bundling area C is bent. That is, the flexibility of the bundling area C can be improved remarkably.

In the flexible wiring module of the first embodiment, the cover lay 12 of the wiring fin 30a in the top layer is removed in the bundling area C, causing the top surface of the electric wiring lines 35 of the wiring fin 30a to be exposed, as shown by a sectional view of FIG. 2B taken along line B-BT of FIG. 1. Then, when the wire-bundle band 40 is wound around a part of the wiring area B as described above, the winding force is adjusted suitably. This enables the exposed part of the electric wiring lines 35 to slide over the wire-bundle band 40 (in a non-adherent manner) and brings the exposed part into direct contact with the wire-bundle band stably. A coated insulator 41 may be formed around the wire-bundle band 40.

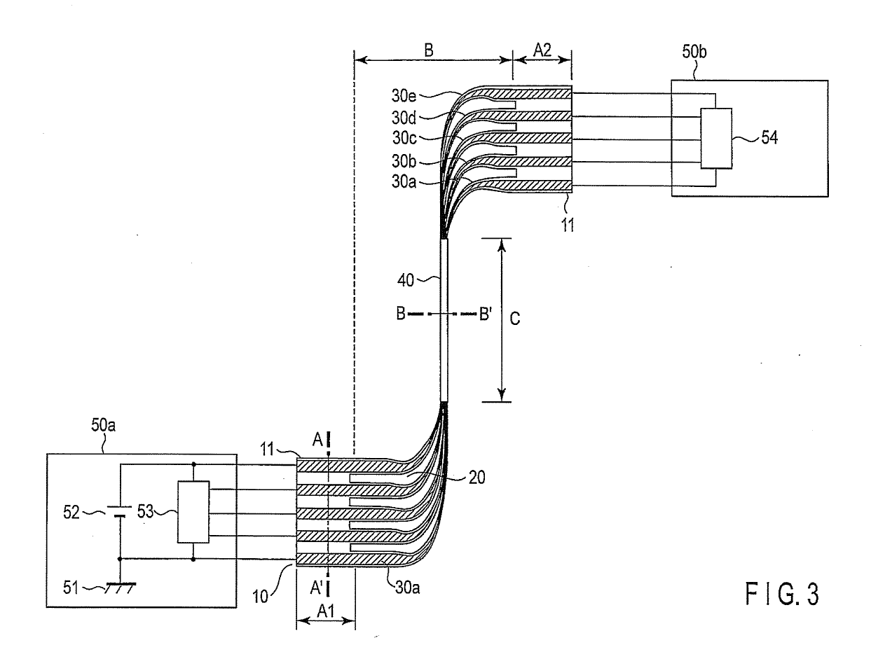

The flexible wiring module is configured as described above, improving the reliability of the flexible wiring device using the module. Specifically, as shown in FIG. 3, an electric circuit 50a comprising, for example, a ground potential 51, a direct-current power supply 52, and a transmitting circuit 53 is connected to a first electric connecting terminal (not shown) of the flexible wiring module on the end area Al side. The electric connecting terminal can be formed by exposing a part of the electric wiring lines 35 and plating their surface with, for example, Ni/Au (5 μm thick/0.3 μm thick). On the other hand, an electric circuit 50b comprising, for example, a receiving circuit 54 is connected to a second electric connecting terminal (not shown) of the flexible wiring module on the end area A2 side.

In such a flexible wiring device, a direct-current potential (e.g., ground potential) is applied to the electric wiring line 35 of the wiring fin 30a in the top layer, enabling the wire-bundle band 40 in contact with the electric wiring line 35 of the wiring fin 30a to be used as a shield. That is, the wire-bundle band 40 acts as a shield. Therefore, electromagnetic noise generated from the electric wiring lines 35 of the wiring fins 30b to 30d as a result of the transmission of a high-speed signal is prevented from radiating outside the flexible wiring module, enabling the radiation of electromagnetic noise to be suppressed. In addition, incoming electromagnetic noise is prevented from being coupled to the electric wiring lines 35 of the wiring fins 30b to 30d, which helps improve the signal transmission quality.

While in FIG. 3, the direct-current power supply 52 of the electric circuit 50a supplies power to the transmitting circuit 53 and the receiving circuit 54, another direct-current power supply may supply power to them. In addition, while in FIG. 2B, the wire-bundle band 40 is caused to contact the electric wiring line of the wiring fin 30a in the top layer, the wire-bundle band 40 may be brought into contact with the electric wiring line 35 of the wiring fin 30e in the bottom layer.

Therefore, with the first embodiment, the slits 20 are made in the flexible wiring board 10 so as to divide the wiring area B into the wiring fins 30 of almost the same width, which enables adjacent wiring fins 30 to be stacked one on top of another in an unfixed manner and to be tied together with the conductive wire-bundle band 40 into one piece. This makes it possible not only to improve the signal transmission quality and suppress the radiation of electromagnetic noise but also to realize a highly flexible wiring module.

Furthermore, in the flexible wiring module of the first embodiment, since the wiring fins 30 (including the wiring fin 30a) are kept unfixed so as to be movable inside the wire-bundle band 40, the flexibility of the bundling area C can be increased remarkably.

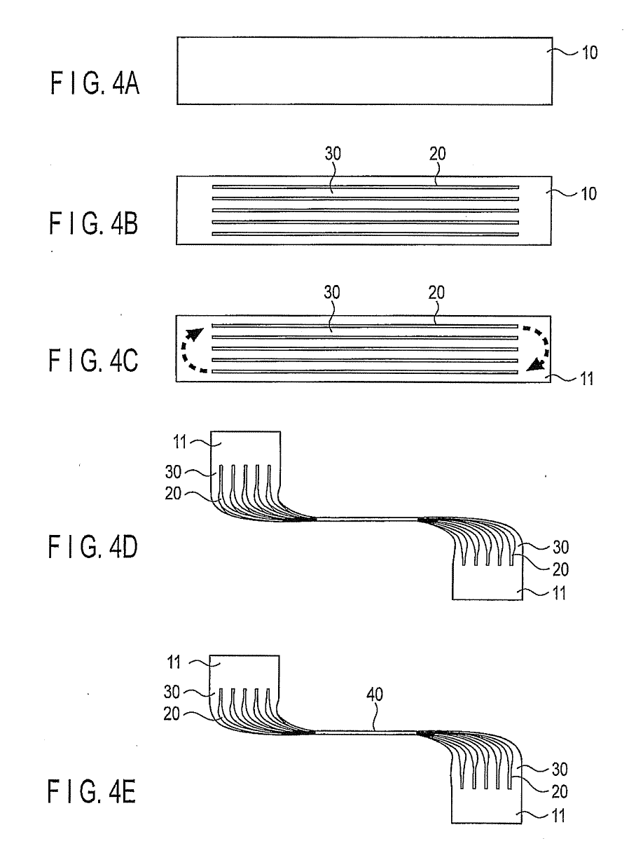

Here, an example of the process of manufacturing the flexible wiring module shown in FIG. 1 will be explained with reference to FIGS. 4A to 4E. FIG. 4A shows a stage where a normal flexible wiring board manufacturing process has been completed and the wiring of a Cu wiring pattern (not shown) and others has been performed. As described above, in this stage, wiring has not been done in a part where through slits are to be made. FIG. 4B shows the process of making a plurality of through slits 20 so as to separate wiring fins 30. Through slits 20 may be made by not only the laser beam machining but also router machining, such as die punching or mechanical cutting.

Next, two end areas 11 are turned inward simultaneously as shown by two dashed arrows in FIG. 4C. As a result of this operation, the individual wiring fins 30 are twisted and pulled in. The positions of the end areas 11 are shifted as shown in FIG. 4D according to the direction in which the end areas 11 were turned so as to apply tension suitably to the end areas 11, which causes the wiring fins 30 to line up in a bundle in such a manner that the adjacent wiring fins 30 are stacked so as to cause the front face of one wiring fin to face the back face of the adjacent one. While this state is kept, the wire-bundle band 40 is wound around the bundle, completing a flexible wiring module as shown in FIG. 4E.

Another method may be used to stack the wiring fins 30. For instance, a plurality of wiring fins may be stacked so as to cause the front face of one wiring fin to face the front face of the adjacent one or the back face of one wiring fin to face the back face of the adjacent one.

### Second Embodiment

FIG. 5 is a schematic sectional view taken along line B-B′ of FIG. 1, showing the configuration of a main part of a flexible wiring module according to a second embodiment. In FIG. 5, the same parts as those of FIG. 2B are indicated by the same reference numerals and a detailed explanation of them will be omitted.

In the first embodiment, the cover lay 12 of the electric wiring line 35 of the wiring fin 30 in the top layer is removed, causing the top surface of the electric wiring line 35 to make direct contact with the wire-bundle band 40. In contrast, in the second embodiment, the side of the electric wiring line 35 is caused to contact the wire-bundle band 40. Specifically, the electric wiring line 35 of the wiring fin 30a in the top layer is made wider than the other electric wiring lines 35 so as to reach the side of the wiring fin 30a.

In this case, before slits are made, the electric wiring line 35 included in the wiring fin 30a of the top layer is made wider than the other electric wiring lines so as to cause the side of the electric wiring line 35 to be exposed to a slit 20 as a result of the formation of the slit 20.

In the second embodiment, when the wiring fins 30 are tied together with the wire-bundle band 40, the side of the electric wiring line 35 of the wiring fin 30a makes direct contact with the wire-bundle band 40, causing the electric wiring line 35 of the wiring fin 30a to be electrically connected to the wire-bundle band 40. Since the side of the electric wiring line 35 has only to be caused to contact the wire-bundle band, the wiring fin 30a of the top layer is not necessarily caused to contact the wire-bundle band. The electric wiring line 35 of another wiring fin 30 may be caused to contact the wire-bundle band 40.

As in the first embodiment, in the second embodiment, the wire-bundle band 40 is composed of a conductive band, producing a shielding effect. In addition, instead of the top face of the electric wiring line 35 of the wiring fin 30a, the side of the electric wiring line 35 is caused to contact the wire-bundle band 40, causing the electric wiring line to be electrically connected to the wire-bundle band 40. Accordingly, the second embodiment produces the same effect as that of the first embodiment.

### Third Embodiment

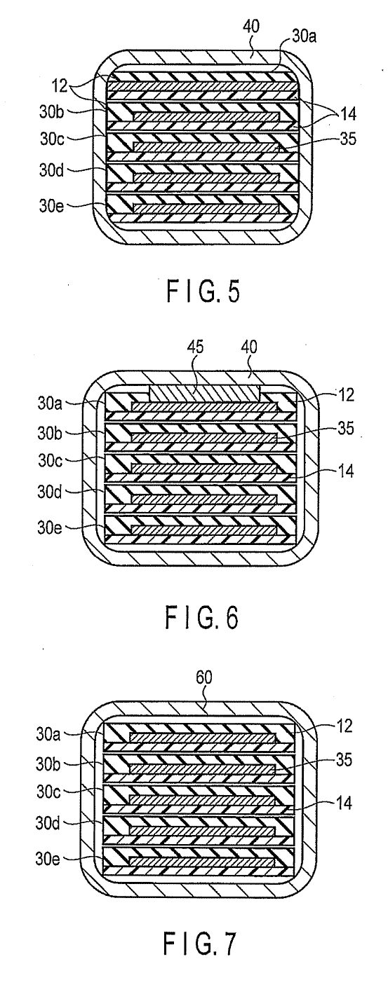

FIG. 6 is a schematic sectional view taken along line B-B′ of FIG. 1, showing the configuration of a main part of a flexible wiring module according to a third embodiment. In FIG. 6, the same parts as those of FIG. 2B are indicated by the same reference numerals and a detailed explanation of them will be omitted.

In the first embodiment, the cover lay 12 of the electric wiring line 35 of the wiring fin 30a in the top layer is removed, causing the top face of the electric wiring line 35 to make direct contact with the wire-bundle band 40. In contrast, in the second embodiment, the wire-bundle band 40 is connected to the top face of the electric wiring line 35 via a conductive adhesive 45.

Specifically, the cover lay 12 of the wiring fin 30a in the top layer is removed. For example, silver paste, anisotropic conductive paste, or anisotropic conductive film is applied as a conductive adhesive 45 to the top face of the electric wiring line 35 of the wiring fin 30a. In this state, after the wire-bundle band 4 is provided, heating or thermocompression bonding is performed. This enables the electric wiring line 35 of the wiring fin 30a and the wire-bundle band 40 to be bonded and electrically connected with each other.

As described above, with the third embodiment, the electric wiring line 35 of the wiring fin 30a is connected to the conductive wire-bundle band 40 via the adhesive 45, producing the same effects as those of the first embodiment, except that the flexibility decreases a little on the whole.

### Fourth Embodiment

FIG. 7 is a schematic sectional view taken along line B-B′ of FIG. 1, showing the configuration of a main part of a flexible wiring module according to a fourth embodiment. In FIG. 7, the same parts as those of FIG. 2B are indicated by the same reference numerals and a detailed explanation of them will be omitted.

Unlike the first embodiment, the fourth embodiment uses a radiowave absorber as a wire-bundle band 60 instead of a conductive material. When a radiowave absorber is used, there is no need to connect the wire-bundle band 60 electrically to the electric wiring line 35 of the wiring fin 30. Therefore, the cover lay 12 need not be removed at the wiring fin 30a of the top layer and may be left as it is.

It is desirable to use a conductive radiowave absorber that absorbs the current induced by electromagnetic waves in an internal resistance of a material. In addition, a dielectric radiowave absorber obtained by mixing carbon powder with a dielectric material, such as rubber, urethane foam, or polystyrene foam, a magnetic radiowave absorber that absorbs radiowaves as a result of magnetic loss which a magnetic material, such as iron, nickel, or ferrite, has may be used. In addition, a combination of these may be used.

This configuration produces the same effects as those of the first embodiment, because the wire-bundle band 60 functions as a shield.

In addition, instead of the wire-bundle band 60 composed of a radiowave absorber of the fourth embodiment, the same conductive material as in the first embodiment may be used. In this case, to apply a direct-current potential, such as the ground potential, to the wire-bundle band 60, a conductive wire to be connected to the wire-bundle band 60 is provided in addition to the wiring fin 30.

(Modification)

The invention is not limited to the above embodiments. The size (length and width) of the flexible wiring board, materials, and others may be determined suitably according to specifications. Similarly, the relationship between the end areas, wiring area, and bundling area may be determined suitably according to specifications. The number of wiring fins, that is, the number of through slits made in the wiring board, is not restrictive. Even if only one wiring fin or through slit is used, an effect can be expected.

Furthermore, the wire-bundle band is not limited to a metal sheet made of Cu foil or Al foil and has only to be a conductive material. For instance, the wire-bundle band may be a metal mesh or include a carbon filler or a metal filler. Although it is most desirable to make through slits so as to cause a plurality of fins to have almost the same width, the invention is not necessarily limited to this. The wiring fins may differ slightly within an allowable range.

In addition, both of a flexible printed circuit (FPC) and a flexible flat cable (FFC) may be applied to the flexible wiring board of the embodiments.

Moreover, the electric wiring lines of the FPC or FFC may be arranged in a single layer or a multilayer.

A flexible wiring board may be a flexible optoelectronic interconnection board in which an optical waveguide is formed and optical signal transmission is available. A flexible wiring board may be a flexible interconnection board module which is comprised of the first flexible wiring board and the 2nd flexible wiring board.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A flexible wiring module comprising:
a flexible wiring board which comprises a plurality of electric wiring lines and an insulating layer that covers the surfaces of the electric wiring lines and which has a pair of end areas separate from each other in a wiring length direction and a wiring area sandwiched between the end areas;
at least one through slit which is in the wiring area so as to connect the end areas and which divides the wiring area into a plurality of wiring fins, and
a band which bundles together a stacked part where at least a part of the wiring fins are stacked in a thickness direction of the wiring fins and which is made of a conductive material.

2. The module of claim 1, wherein the band bundles the wiring fins together in an unfixed manner.

3. The module of claim 1, wherein the band is connected electrically to the electric wiring line of at least one of the wiring fins.

4. The module of claim 1, wherein the wiring fin of the outermost layer in the wiring fins has the surface of its electric wiring line exposed and the exposed surface is connected electrically to the band.

5. The module of claim 4, wherein the band is direct contact with the surface of the surface-exposed electric wiring line in an unfixed manner.

6. The module of claim 4, wherein the band is bonded to the surface of the surface-exposed electric wiring line via a conductive adhesive.

7. The module of claim 1, wherein the band is a conductive foil made of Cu or Al.

8. The module of claim 1, wherein the band is further covered with a coated insulating film.

9. The module of claim 1, wherein the wiring fins are stacked so as to cause the front faces and back faces of adjacent wiring fins to face one another.

10. A flexible wiring module comprising:
a flexible wiring board which comprises a plurality of electric wiring lines and an insulating layer that covers the surfaces of the electric wiring lines and which has a pair of end areas separate from each other in a wiring length direction and a wiring area sandwiched between the end areas;
at least one through slit which is in the wiring area so as to connect the end areas and which divides the wiring area into a plurality of wiring fins, and
a band which bundles together a stacked part where at least a part of the wiring fins are stacked in a thickness direction of the wiring fins and which is made of a radiowave absorbent material.

11. The module of claim 10, wherein the band bundles the wiring fins together in an unfixed manner.

12. The module of claim 10, wherein the band is a conductive radiowave absorber, a dielectric radiowave absorber, a magnetic radiowave absorber, or a combination of these.

13. A flexible wiring device comprising:
a flexible wiring board which comprises a plurality of electric wiring lines and electric connecting terminals for connecting the electric wiring lines to the outside and which has a pair of end areas separate from each other in a wiring length direction and a wiring area sandwiched between the end areas;
at least one through slit which is in the wiring area so as to connect the end areas and which divides the wiring area into a plurality of wiring fins, a conductive band which bundles together a stacked part where at least a part of the wiring fins are stacked in a thickness direction of the wiring fins and which is connected electrically to the electric wiring line of at least one of the wiring fins; and
an electric circuit which is connected to the electric connecting terminals of the wiring board and which applies a direct-current potential to the electric wiring line in contact with the band.

14. The device of claim 13, wherein the band bundles the wiring fins together in an unfixed manner.

15. The device of claim 13, wherein the wiring fin of the outermost layer in the wiring fins has the surface of its electric wiring line exposed and the exposed surface is connected electrically to the band.

16. The device of claim 15, wherein the band is direct contact with the surface of the surface-exposed electric wiring line in an unfixed manner.

17. The device of claim 13, wherein the band is bonded to the surface of the surface-exposed electric wiring line via a conductive adhesive.

18. The device of claim 13, wherein the band is a conductive foil made of Cu or Al.

19. The device of claim 13, wherein the band is further covered with a coated insulating film.

20. The device of claim 13, wherein the wiring fins are stacked so as to cause the front faces and back faces of adjacent wiring fins to face one another.
